(19) United States
(12) Patent Application Publication
(10) Pub. No.: US 2020/0200830 A1
(43) Pub. Date: Jun. 25, 2020

(54) Determining the charge of a rechargeable battery in a charging process

(71) Applicant: Hilti Aktiengesellschaft, Schaan (LI)

(72) Inventors: Klaus HAUSER, Schwabmuenchen (DE); David KOSCHECK, Augsburg (DE); Stefan MAYER, Dachau (DE)

(21) Appl. No.: 16/641,162

(22) PCT Filed: Aug. 13, 2018
(86) PCT No.: PCT/EP2018/071894

§ 371 Date: Feb. 21, 2020

(30) Foreign Application Priority Data
Aug. 23, 2017 (EP) 17187423.3

(51) Int. Cl. G01R 31/3828; H02J 7/00; H01M 10/44; H01M 10/48

(52) U.S. Cl. CPC G01R 31/3828; H01M 10/48; H01M 10/44; H02J 7/0048

(57) ABSTRACT

A method for determining a charge value for a system containing a charging apparatus and a rechargeable battery. The rechargeable battery can be connected to the charging apparatus to receive and store electrical energy. The method includes detecting a first charge value of an electrical charge of the rechargeable battery at a first time instant; detecting a current value of an electric current flowing from the charging apparatus to the rechargeable battery to charge the rechargeable battery, between a first time instant and second time instant; determining a second charge value on the basis of the detected current value between the first time instant and second time instant; and adding the second charge value from the first charge value in order to determine a third charge value in the rechargeable battery at the second time instant. A rechargeable battery, a charging apparatus, and a system containing a battery and a charging apparatus for performing the method are also provided.

The present invention relates to a method for determining a charge value for a system containing a charging apparatus and at least one rechargeable battery, wherein the at least one rechargeable battery can be connected to the charging apparatus in order to receive and store electrical energy.

### BACKGROUND

The present invention also relates to a rechargeable battery and to a charging apparatus for performing the method. In addition, the present invention relates to a system containing at least one rechargeable battery and a charging apparatus for performing the method.

Cordless power tools can be operated with a rechargeable battery for the purpose of supplying power. The cordless power tool may be, for example, a rechargeable battery-operated screwdriver, a hammer drill, or suchlike.

Rechargeable batteries usually contain a number of storage cells, or energy storage cells, for electrical energy or electrical charge. For the purpose of controlling a charging or discharging process of the storage cells, in which charging or discharging process the storage cells are either charged with electrical energy or electrical energy is drawn from the storage cells, modern rechargeable batteries have a controller or electronic control system. The storage cells are also referred to as rechargeable battery cells.

Usually for reasons of cost, rechargeable batteries according to the prior art do not have an apparatus for displaying reliably and precisely at any given time the prevailing state of charge or the status of the amount of stored energy of the rechargeable battery.

Detecting as accurately as possible the prevailing state of charge, or the amount of energy already stored in the rechargeable battery, however, allows improved monitoring of a charging process, and in particular a better judgement of the time at which the rechargeable battery has reached a certain state of charge.

Detecting as accurately as possible the prevailing state of charge, or the amount of energy already stored in the rechargeable battery is additionally used to make a better assessment of how long it will still take the charging apparatus to charge the rechargeable battery with electrical energy to a certain state of charge.

### SUMMARY OF THE INVENTION

According to the prior art, it is already possible to determine the prevailing or actual state of charge (i.e. the amount of charge or amount of energy already stored in the rechargeable battery) by measuring the no-load voltage of the rechargeable battery. This measurement, however, is only possible in a situation in which no electric current is flowing from the charging apparatus to the rechargeable battery. Automatic interruption of the charging process may happen, for example, if the rechargeable battery and/or the charging apparatus have become too hot during the charging process. In such a case, a charging process cannot be resumed safely until the rechargeable battery or the charging apparatus have cooled down again sufficiently.

An object of the present invention is a method for determining a charge value for a system containing a charging apparatus and at least one rechargeable battery, wherein the at least one rechargeable battery can be connected to the charging apparatus in order to receive and store electrical energy. It is also an alternative or additional object of the present invention to provide a rechargeable battery, a power tool, and a system containing at least one rechargeable battery and a charging apparatus for performing the method.

The present invention provides a method for determining a charge value for a system containing a power tool and at least one rechargeable battery, the at least one rechargeable battery being used to supply the power tool with electrical energy.

According to the invention, the following steps are provided for the method:
detecting a first charge value of an electrical charge of the at least one rechargeable battery at a first time instant;
detecting a current value of an electric current flowing from the charging apparatus to the at least one rechargeable battery to charge the at least one rechargeable battery, between a first time instant and second time instant;
determining a second charge value on the basis of the detected current value between the first time instant and second time instant; and
adding the second charge value from the first charge value in order to determine a third charge value in the rechargeable battery at the second time instant.

Thereby, or especially by determining the third charge value, it is possible to determine the prevailing or actual state of charge of the rechargeable battery reliably even during the process of charging the rechargeable battery, i.e. when electric current is flowing from the charging apparatus to the rechargeable battery. It is hence possible at any given time during the charging process to judge accurately the energy or electrical charge already stored in the rechargeable battery for forthcoming jobs, or to assess the time until a certain state of charge is reached.

According to an advantageous embodiment, it is also possible for the first charge value of an electrical charge of the at least one rechargeable battery to be stored in a non-volatile memory (NVM).

The time period between the first time instant and second time instant can also be referred to as the first time interval. The time period between the second time instant and the third time instant can also be referred to as the second time interval.

The present invention also provides a rechargeable battery, which can be connected to a charging apparatus and which is configured to perform the method. The rechargeable battery can contain a charge measuring apparatus for detecting a first charge value of an electrical charge in the rechargeable battery.

The present invention also provides a charging apparatus, which can be connected to a rechargeable battery, for performing the method. The charging apparatus can contain a current measuring apparatus for detecting in the charging apparatus a current value of an electric current flowing from the charging apparatus to the at least one rechargeable battery to charge the rechargeable battery. The charging apparatus can also contain a processor for determining a second charge value on the basis of the detected current value between a first time instant and second time instant.

The present invention also provides a system containing at least one rechargeable battery and a charging apparatus for performing the method.

Further advantages can be found in the description of the figures that follows. The figures depict various exemplary embodiments of the present invention. The figures, the description and the claims contain numerous features in combination. A person skilled in the art will expediently also consider the features individually and combine them to produce useful further combinations.

### BRIEF DESCRIPTION OF THE DRAWINGS

In the figures:

FIG. 1 shows a sectional view of a charging apparatus according to the invention comprising a rechargeable battery according to the invention, which is connected to the charging apparatus.

### DETAILED DESCRIPTION

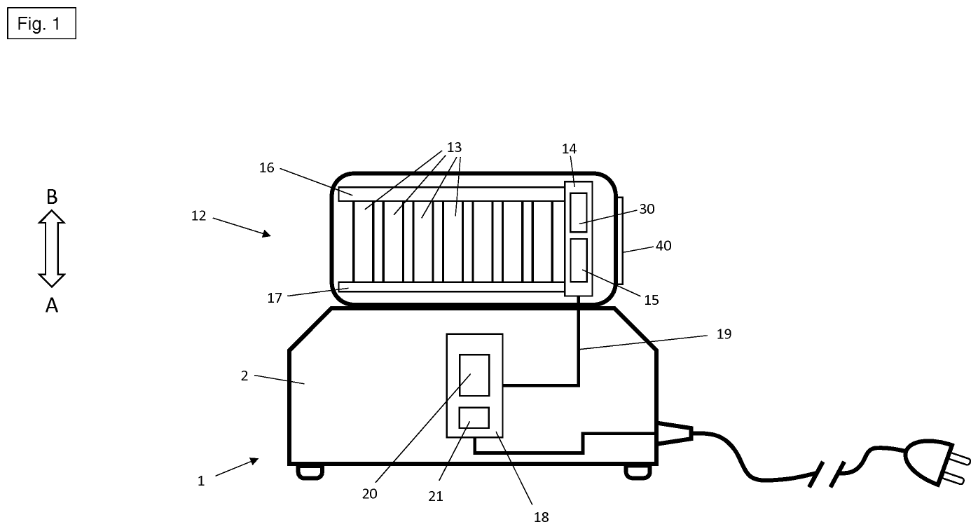

FIG. 1 shows a charging apparatus 1 according to the invention together with a rechargeable battery 12 according to the invention. The rechargeable battery 12 is detachably connected to the charging apparatus 1 for a charging process which charges the rechargeable battery 12 with electrical energy.

The charging apparatus 1 is in the form of a battery charger, for example, and substantially contains a housing 2 and a power supply cable. The power supply cable is used to connect the charging apparatus 1 to a grid power source (also referred to as a power outlet) in order to allow electric current to flow from the grid power source to the charging apparatus 1.

In one embodiment, the rechargeable battery 12 can be used to supply a power tool 1 with electrical energy or electric current. To this end, the rechargeable battery 12 is disconnected from the charging apparatus 1 and connected to a power tool. The power tool may be, for example, a rechargeable battery-operated screwdriver, a power drill, a saw, or suchlike. The power tool is not depicted in the figure.

To this end, the rechargeable battery 12 contains substantially internally a number of energy storage cells 13 (also called rechargeable battery cells) and also a controller 14. The energy storage cells 13 and the controller 14 are connected to one another. Electrical energy or an electrical charge can be stored by means of the energy storage cells 13.

The controller 14 of the rechargeable battery 12 in turn contains a charge measuring apparatus 15. The charge measuring apparatus 15 is used to detect a first charge value of an electrical charge stored in the energy storage cells 13. The first charge value equals the electrical charge available in the energy storage cells 13 at a specific time instant.

The individual energy storage cells 13 are mechanically and electrically connected to the controller 14 by means of an upper and a lower cell holder 16, 17, so that electrical energy or electric current can flow from the individual energy storage cells 13 to the controller 14. The charge measuring device 15 contained in the controller 14 measures at time intervals, i.e. at specific time instants, the electrical charge stored in the energy storage cells 13. The values of the measured electrical charge are stored in a non-volatile memory 30.

A control apparatus 18 is positioned inside the housing 2 of the charging apparatus 1. The control apparatus 18 is connected to the controller 14 of the rechargeable battery 12 via a corresponding lines 19. The lines 19 are used to transfer signals, i.e. as a communications line, and to transfer electric current.

The control apparatus 18 also contains a current measuring apparatus 20 and a processor 21.

The current measuring apparatus 20 is used to detect a current value of an electric current that is flowing from the charging apparatus 1 to the individual energy storage cells 13 of the rechargeable battery 12. The electric current flows from the charging apparatus 1 to the energy storage cells 13 in order to charge the rechargeable battery 12. For the purpose of charging the rechargeable battery 12, electrical energy or an electrical charge is stored in the energy storage cells 13. The detection or measurement of the current value takes place between a first time instant t₁ and second time instant t₂ for a specific time length or for a specific time interval.

In order to perform the method according to the invention, the rechargeable battery 12 is placed onto the charging apparatus 1 in arrow direction A. The rechargeable battery 12 and the charging apparatus 1 each comprise a mutually mating interface for this purpose, so that the rechargeable battery 12 and the charging apparatus 1 are connected to each other mechanically, electrically and electronically. The respective interfaces of the rechargeable battery 12 and charging apparatus 1 are not depicted in the figure. The rechargeable battery 12 is moved in arrow direction B in order to disconnect the rechargeable battery 12 again from the charging apparatus 1.

First, the prevailing electrical charge Q(t₁) in the energy storage cells 13 is detected at a specific first time instant t₁. The charge measuring apparatus 15 in the rechargeable battery 12 is used to perform the detection or measurement of the charge Q(t₁). The value of the prevailing electrical charge Q(t₁) is stored in the memory 30. In this case, also a plurality of values of the electrical charge can be stored systematically in the memory 30. The controller 14 of the rechargeable battery 12 sends the value of the prevailing electrical charge Q(t₁) via the line 19 to the control apparatus 18 of the power tool 1.

If the rechargeable battery 12 is connected to the charging apparatus 1 for a charging process, an electrical charge or electric current flows from the charging apparatus 1 via the control apparatus 18, the line 19, the controller 14 and to the energy storage cells 13 of the rechargeable battery 12.

The current measuring apparatus 20 of the control apparatus 18 detects the amount of electric current that flows in a first time interval, i.e. between a first time instant t₁ and second time instant t₂, from the charging apparatus 1 to the energy storage cells 13.

Using the equations:

Q=I×t

Q (t₃)=Q(t₁)+fₜ_{₁}^{t}^{₂}I(t) dt

where

Q (t₃)=total electrical charge in the energy storage cells 13 at the third time instant t₃;

Q (t₁)=prevailing electrical charge in the energy storage cells 13 at the first time instant;

I=current in amperes (A or mA)

t=time

t₁ to t₂=time interval between a first time instant and second time instant,

the processor 21 determines the electrical charge as the integral over the time interval, i.e. between the first time instant t₁ and the second time instant t₂, of the electric current that flows from the charging apparatus 1 to the rechargeable battery 12 for the charging process.

Determining the electrical charge makes use of the fact that the integral of the electric current over time represents the electrical charge that has flowed into, or through, a body.

The control apparatus 18 sends via the lines 19 to the controller 14 of the rechargeable battery 12 the value of the electrical charge determined in the charging apparatus 1 (i.e. the integral over time of the electric current that has flowed). In the controller 14 of the rechargeable battery 12, the value of the determined electrical charge is added to the detected electrical charge Q(t₁), thereby determining the electrical charge Q (t₃) already actually stored in the energy storage cells 13 at the third time instant t₃. In other words: the electrical charge Q(t₁) determined in the rechargeable battery 12, and the charge calculated by the charging apparatus 1 together give the total charge Q(t₃).

The determined electrical charge Q(t₃) currently already available at time instant t₃ can be displayed on a display apparatus 40 on the rechargeable battery 12. The user of the power tool is hence informed of how much electrical energy is actually already available from the rechargeable battery 12.

According to a further embodiment (not shown in the figures), it is also possible that the display apparatus 40 for displaying the determined electrical charge Q(t₃) currently already available in the rechargeable battery 12 at time instant t₃ is positioned on the charging apparatus 1.

In addition, according to a further embodiment (not shown in the figures), it is also possible that the display of the determined electrical charge Q(t₃) currently already available in the energy storage cells 13 at time instant t₃ is sent to an external display apparatus by means of a wireless connection. For example, the external display apparatus may be augmented-reality glasses, a smartphone or suchlike.

1-4. (canceled)

5. A method for determining a charge value for a system including a charging apparatus and at least one rechargeable battery, the at least one rechargeable battery being connectable to the charging apparatus to receive and store electrical energy, the method comprising the following steps:
detecting a first charge value of an electrical charge of the at least one rechargeable battery at a first time instant;
detecting a current value of an electric current flowing from the charging apparatus to the at least one rechargeable battery to charge the at least one rechargeable battery, between a first time instant and second time instant;
determining a second charge value on the basis of the detected current value between the first time instant and second time instant; and
adding the second charge value from the first charge value to determine a third charge value in the rechargeable battery at the second time instant.

6. A rechargeable battery connectable to a charging apparatus for performing the method as recited in claim 5, the rechargeable battery comprising:
a charge measurer for detecting the first charge value of the electrical charge in the rechargeable battery.

7. A charging apparatus connectable to a rechargeable battery for performing the method as recited in claim 5, the charging apparatus comprising:
a current measurer for detecting the current value of the electric current in the charging apparatus flowing from the charging apparatus to the least one rechargeable battery to charge the at least one rechargeable battery, and
a processor for determining the second charge value on the basis of the detected current value between the first time instant and the second time instant.

8. A system comprising at least one rechargeable battery and a charging apparatus for performing the method as recited in claim 5.
